(19) United States
(12) Patent Application Publication
(10) Pub. No.: US 2022/0122811 A1
(43) Pub. Date: Apr. 21, 2022

(54) ELECTRIC ARC MITIGATING FACEPLATE

(71) Applicant: Applied Materials, Inc., Santa Clara, CA (US)

(72) Inventors: Madhu Santosh Kumar Mutyala, Santa Clara, CA (US); Sanjay Kamath, Fremont, CA (US); Deenesh Padhi, Sunnyvale, CA (US); Mayur Govind Kulkarni, Bangalore (IN); Arun Thottappayil, Bangalore (IN)

(73) Assignee: Applied Materials, Inc., Santa Clara, CA (US)

(21) Appl. No.: 17/072,673

(22) Filed: Oct. 16, 2020

(51) Int. Cl. H01J 37/32; H01L 21/02; C23C 16/40; C23C 16/50

(52) U.S. Cl. CPC H01J 37/32477; H01L 21/02274; H01J 37/3244; H01L 21/02214; C23C 16/50; H01L 21/02164; C23C 16/401

(57) ABSTRACT

Exemplary deposition methods may include forming a plasma of an oxygen-containing precursor within a processing region of a semiconductor processing chamber. The processing region may house a semiconductor substrate on a substrate support. The methods may include, while maintaining the plasma of the oxygen-containing precursor, flowing a silicon-containing precursor through a faceplate into the processing region of the semiconductor processing chamber. The faceplate may have an impedance of at least 5.75 deciohm. The methods may include depositing a silicon-containing material on the semiconductor substrate.

### TECHNICAL FIELD

The present technology relates to semiconductor systems and processes. More specifically, the present technology relates to components facilitating material deposition.

### BACKGROUND

Integrated circuits are made possible by processes which produce intricately patterned material layers on substrate surfaces. Producing patterned material on a substrate requires controlled methods of formation and removal of exposed material. Material properties of films produced may contribute to substrate effects, which may cause wafer bowing or other challenges during processing.

Thus, there is a need for improved systems and methods that can be used to produce high quality devices and structures. These and other needs are addressed by the present technology.

### SUMMARY

Exemplary deposition methods may include forming a plasma of an oxygen-containing precursor within a processing region of a semiconductor processing chamber. The processing region may house a semiconductor substrate on a substrate support. The methods may include, while maintaining the plasma of the oxygen-containing precursor, flowing a silicon-containing precursor through a faceplate into the processing region of the semiconductor processing chamber. The faceplate may have an impedance of at least about 5.75 deciohm. The methods may include depositing a silicon-containing material on the semiconductor substrate.

In some embodiments, the silicon-containing precursor may be or include tetraethyl orthosilicate. The depositing may be performed at a temperature of greater than or about 450° C. The depositing may be performed at a pressure of greater than or about 8 torr. At least about 10% of an area of the faceplate that is exposed to an interior of the chamber may be formed by a plurality of apertures defined by the faceplate. The faceplate may include at least or about 75 rows of apertures. The faceplate may define greater than or about 25,000 apertures. The faceplate may define a plurality of apertures arranged in a uniform manner about a surface of the faceplate. Centers of adjacent ones of the plurality of apertures may be spaced apart by less than or about 80 mils.

Some embodiments of the present technology may encompass deposition methods. The methods may include flowing an oxygen-containing precursor into a processing region of a semiconductor processing chamber. The processing region may house a semiconductor substrate on a substrate support. The methods may include forming a plasma of the oxygen-containing precursor. The methods may include flowing a silicon-containing precursor through a faceplate into the processing region of the semiconductor processing chamber. The faceplate may define a plurality of apertures. At least about 10% of an area of the faceplate that is exposed to an interior of the chamber is formed by the plurality of apertures. The methods may include depositing a first amount of a silicon-containing material on the semiconductor substrate.

In some embodiments, a distance between outermost apertures of the plurality of apertures that are proximate opposing sides of the faceplate may be about or at least 13 inches. Each of the plurality of apertures may include an aperture profile having a first generally cylindrical section extending through the first surface of the faceplate and a second generally cylindrical section extending through the second surface of the faceplate. A diameter of the first generally cylindrical section may be more than or about 1.3× greater than a diameter of the second generally cylindrical section. The first generally cylindrical section may extend at least or about halfway through a thickness of the faceplate. The depositing may be performed at a temperature of greater than or about 450° C. and a pressure of at least about 8 torr.

The present technology may encompass semiconductor processing chambers. The chambers may include a chamber body. The chambers may include a substrate support disposed within the chamber body. The chambers may include a gas distributor. The gas distributor may include a faceplate. The faceplate may be characterized by a first surface and a second surface opposite the first surface. The second surface may face the substrate support. The second surface of the faceplate and the substrate support may at least partially define a processing region within the semiconductor processing chamber. The faceplate may define a plurality of apertures through a thickness of the faceplate. The faceplate may have an impedance of at least about 5.75 deciohm. At least about 10% of an area of the faceplate that is exposed to an interior of the chamber may be formed by the plurality of apertures.

In some embodiments, each of the plurality of apertures may include a generally cylindrical aperture profile. The aperture profile of each of the plurality of apertures may include an additional cylindrical section that extends through the first surface of the faceplate. The additional cylindrical section may have a greater diameter than the generally cylindrical aperture profile. A diameter of the generally cylindrical aperture profile may be less than or about 35 mils. A diameter of the additional cylindrical section may be less than or about 50 mils. The plurality of apertures may include at least or about 25,000 apertures.

Such technology may provide numerous benefits over conventional systems and techniques. For example, the processes may produce films characterized by reduced film shrinking, while eliminating the occurrence of electrical arcing between the faceplate and the semiconductor substrate. Additionally, the operations of embodiments of the present technology may produce improved film strength on a substrate. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary processing chamber according to some embodiments of the present technology.

FIG. 2 shows a schematic cross-sectional view of an exemplary faceplate according to some embodiments of the present technology.

FIG. 3 shows exemplary operations in a deposition method according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

During semiconductor fabrication, structures may be produced on a substrate utilizing a variety of deposition and etching operations. Silicon oxide and other silicon-containing materials are routinely formed in a number of operations for developing semiconductor substrates. Silicon oxide, as one example, may be deposited in a number of processes including chemical vapor deposition and plasma deposition. Silicon oxide deposited or formed in some processes may be characterized by an amount of hydrogen and/or carbon incorporated in the film, which may have been included in the precursors, such as silane or tetraethyl orthosilicate. During subsequent processing, the silicon oxide film may be exposed to high temperatures, such as during subsequent annealing, for example. This high temperature exposure may cause an amount of outgassing of residual materials incorporated during the deposition process, which may cause the film to shrink. Silicon oxide may be characterized by a compressive stress, and when shrinking or densifying, the compressive stress may increase. This may cause high aspect ratio features to buckle, and in some circumstances may cause substrate or wafer bowing.

To limit shrinking effects, conventional semiconductor processing chambers may be maintained at a higher pressure, such as about or greater than 8 torr. Films produced in chambers with such combinations of high internal chamber temperatures and high internal chamber pressures are more resistant to shrinking. Additionally, such films may exhibit greater strength on the wafer. However, conventional semiconductor processing chambers that maintain operating conditions that involve high temperatures and pressures often experience electrical arcing between a faceplate and the wafer at plasma ignition. This arcing is attributable to a low impedance of conventional faceplates, which leads to a large impedance change at plasma ignition. The large impedance change results in an abrupt increase in impedance that causes the arcing. Such arcing damages the faceplate and causes defects on wafer.

The present technology may overcome these limitations by implementing a faceplate that has an increased impedance, which reduces the magnitude of the impedance change and smooths the impedance curve at plasma ignition to eliminate any arcing. By eliminating arcing, the integrity of the faceplate and wafer film are improved, enabling high temperature and high pressure fabrication processes to be implemented. As indicated above, these high temperature and high pressure processes reduce film shrinkage and improve film strength on wafer. After describing general aspects of a chamber according to embodiments of the present technology in which plasma processing may be performed, specific methodology and component configurations may be discussed. It is to be understood that the present technology is not intended to be limited to the specific films and processing discussed, as the techniques described may be used to improve a number of film formation processes, and may be applicable to a variety of processing chambers and operations.

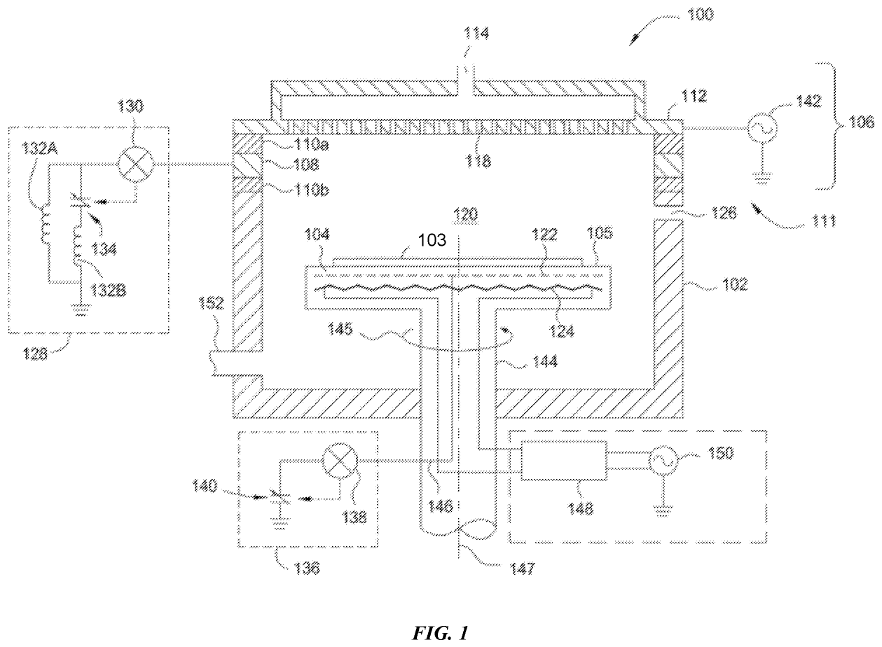

FIG. 1 shows a cross-sectional view of an exemplary processing chamber 100 according to some embodiments of the present technology. The figure may illustrate an overview of a system incorporating one or more aspects of the present technology, and/or which may perform one or more operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as a radio frequency (RF) generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

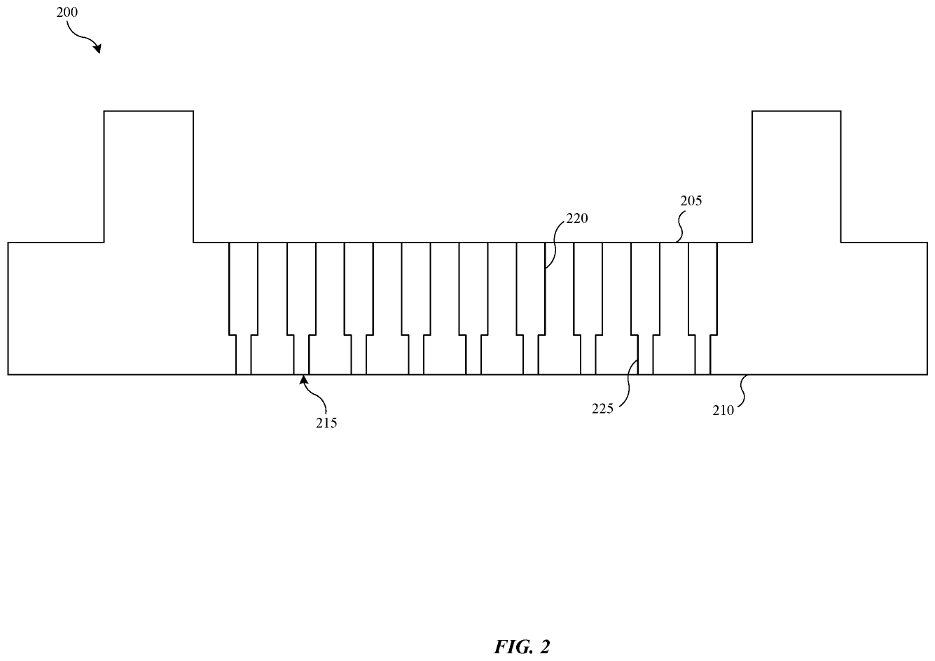

FIG. 2 shows a schematic partial cross-sectional view of an exemplary faceplate 200 according to some embodiments of the present technology. FIG. 2 may illustrate further details relating to components in chamber 100, such as for a faceplate of gas distributor 112. The faceplate 200 may be used to perform semiconductor processing operations including deposition of materials as previously described, as well as other deposition, removal, and cleaning operations. Faceplate 200 may show a partial view of a faceplate that may be incorporated in a semiconductor processing system, and may illustrate a view across a center of the faceplate, which may otherwise be of any size, and include any number of apertures. Although shown with a number of apertures extending outward laterally or radially, it is to be understood that the figure is included only for illustration of embodiments, and is not considered to be of scale. For example, exemplary faceplates may be characterized by a number of apertures 215 along a central diameter of the faceplate 200 of greater than or about 150 apertures, greater than or about 160 apertures, greater than or about 170 apertures, greater than or about 180 apertures, greater than or about 190 apertures, greater than or about 200 apertures, greater than or about 210 apertures, greater than or about 220 apertures, or more. As will be discussed in greater detail below, in some embodiments the apertures 215 may be arranged in a number of rows or rings. The number of apertures 215 along the central diameter may reflect the number of rings and/or rows of apertures 215 about the faceplate 200. For example, the number of apertures 215 along a central diameter of the faceplate 200 may be approximately double a number of rows or rings of apertures 215 provided on the faceplate 200.

As noted, faceplate 200 may be included in any number of processing chambers, including chamber 100 described above. Faceplate 200 may be included as part of the gas distributor 112. For example, a gas distributor may define or provide fluid access into a processing chamber. A substrate support may be included within the chamber, and may be configured to support a substrate for processing. Faceplate 200 may be characterized by a first surface 205 and a second surface 210, which may be opposite the first surface. In some embodiments, first surface 205 may be facing towards a gas inlet into the processing chamber. Second surface 210 may be positioned to face a substrate support or substrate within a processing region of a processing chamber. For example, in some embodiments, the second surface 210 of the faceplate and the substrate support may at least partially define a processing region within the chamber.

Faceplate 200 may define a plurality of apertures 215 defined through the faceplate and extending from the first surface through the second surface. Each aperture 215 may provide a fluid path through the faceplate 200, and the apertures 215 may provide fluid access to the processing region of the chamber. Depending on the size of the faceplate, and the size of the apertures, faceplate 200 may define any number of apertures 215 through the plate, such as greater than or about 25,000 apertures, greater than or about 27,500 apertures, greater than or about 30,000 apertures, greater than or about 32,500 apertures, greater than or about 35,000 apertures, greater than or about 37,500 apertures, greater than or about 40,000 apertures, greater than or about 42,500 apertures, greater than or about 45,000 apertures, or more. The apertures 215 may be included in a set of rows or rings extending outward from a central axis of the faceplate 200, and may include any number of rings as described previously. For example, the faceplate 200 may include greater than or about 75 rings, greater than or about 80 rings, greater than or about 85 rings, greater than or about 90 rings, greater than or about 95 rings, greater than or about 100 rings, greater than or about 105 rings, greater than or about 110 rings, or more. The rings may be characterized by any number of shapes including circular or elliptical, as well as any other geometric pattern, such as rectangular, hexagonal, or any other geometric pattern that may include apertures 215 distributed in a radially outward number of rings. The apertures 215 may have a uniform or staggered spacing, and may be spaced apart at less than or about 80 mils from center to center. The apertures may also be spaced apart at less than or about 77.5 mils, less than or about 75 mils, less than or about 72.5 mils, less than or about 70 mils, less than or about 67.5 mils, less than or about 65 mils, less than or about 62.5 mils, less than or about 60 mils, or less.

The rings may be characterized by any geometric shape as noted above, and in some embodiments, apertures may be characterized by a scaling function of apertures per ring. For example, in some embodiments a first aperture may extend through a center of the faceplate 200, such as along the central axis as illustrated. A first ring of apertures may extend about the central aperture, and may include any number of apertures, such as between about 4 and about 10 apertures, which may be spaced equally about a geometric shape extending through a center of each aperture. Any number of additional rings of apertures may extend radially outward from the first ring, and may include a number of apertures that may be a function of the number of apertures in the first ring. For example, the number of apertures in each successive ring may be characterized by a number of apertures within each corresponding ring according to the equation XR, where X is a base number of apertures, and R is the corresponding ring number. The base number of apertures may be the number of apertures within the first ring, and in some embodiments may be some other number. For example, for an exemplary faceplate having 5 apertures distributed about the first ring, and where 5 may be the base number of apertures, the second ring may be characterized by 10 apertures, (5)×(2), the third ring may be characterized by 15 apertures, (5)×(3), and the twentieth ring may be characterized by 100 apertures, (5)×(20). This may continue for any number of rings of apertures as noted previously, such as up to, greater than, or about 220 rings. In some embodiments each aperture of the plurality of apertures across the faceplate may be characterized by an aperture profile, which may be the same or different in embodiments of the present technology. In some embodiments, a distance between outermost apertures 215 on either side of the faceplate 200 may be about or at least 13 inches, about or at least 13.05 inches, about or at least 13.1 inches, about or at least 13.15 inches, about or at least 13.2 inches, about or at least 13.25 inches, about or at least 13.3 inches, about or at least 13.35 inches, about or at least 13.4 inches, about or at least 13.45 inches, about or at least 13.5 inches, about or at least 13.55 inches, about or at least 13.6 inches, or more. While illustrated with each aperture 215 having a same or similar shape, spacing, and/or size, it t will be appreciated that some faceplates may utilize apertures with different shapes, spacing, and/or sizes.

The apertures 215 may include any shape. In one non-limiting example as illustrated, the faceplate 200 includes apertures 215 that each have an aperture profile including at least two sections. For example, first section 220 may extend from the first surface 205 of the faceplate 200, and may extend partially through the faceplate 200. In some embodiments, the first section 220 may extend at least about or greater than halfway, or 75% of the way through a thickness of the faceplate between first surface 205 and second surface 210. First section 220 may be characterized by a substantially cylindrical profile as illustrated. By substantially is meant that the profile may be characterized by a cylindrical profile, but may account for machining tolerances and parts variations, as well as a certain margin of error. A second section 225 may extend from the second surface 210 of the faceplate 200, and may extend partially through the faceplate 200 and fluidly couple with the bottom end of the first section 220. Second section 225 may be characterized by a substantially cylindrical profile as illustrated. A diameter of the second section 225 may be less than a diameter of the first section 220. For example, the diameter of the first section 220 may be more than 1.3×, more than 1.4×, more than 1.5×, more than 1.6×, more than 1.7×, or greater than the diameter of the second section 225.

In some embodiments, the diameter of the first section 220 of at least some of the apertures 215 may be less than or about 50 mils, less than or about 47.5 mils, less than or about 45 mils, less than or about 42.5 mils, less than or about 40 mils, less than or about 37.5 mils, or less. The diameter of the second section 225 of at least some of the apertures 215 may be less than or about 35 mils, less than or about 34 mils, less than or about 33 mils, less than or about 32 mils, less than or about 31 mils, less than or about 30 mils, less than or about 29 mils, less than or about 28 mils, less than or about 27 mils, or less.

By having a large number of apertures 215 that are tightly spaced together, a significant area of the faceplate 200 may be formed from the apertures 215. For example, an area of the portion of the faceplate 200 that is exposed to the interior of the chamber (e.g., a portion of the faceplate 200 within an inner diameter of an isolator (such as isolators 110a, 110b) may be formed of at least or about 10% apertures, at least or about 11% apertures, at least or about 12% apertures, at least or about 13% apertures, at least or about 14% apertures, at least or about 15% apertures, at least or about 16% apertures, at least or about 17% apertures, at least or about 18% apertures, at least or about 19% apertures, at least or about 20% apertures, or more. By having a large percentage of the faceplate area being formed of apertures 215, an amount of metal material used to form the faceplate 200 is significantly reduced. The reduction in metal material and metal area may increase the impedance of the faceplate 200. For example, the faceplate 200 may be characterized by a base impedance prior to plasma generation of greater than or about 5.75 deciohms, and this impedance may increase after plasma is struck.

Accordingly, in some embodiments either a base impedance or an impedance during plasma generation may be greater than or about 5.75 deciohms, and may be greater than or about 5.8 deciohms, greater than or about 5.85 deciohms, greater than or about 5.9 deciohms, greater than or about 5.95 deciohms, greater than or about 6.0 deciohms, greater than or about 6.25 deciohms, greater than or about 6.5 deciohms, greater than or about 6.75 deciohms, greater than or about 7.0 deciohms, or more. The increased impedance of the faceplate 200 in turn reduces a difference in impedance between an inactive state of the faceplate 200 and at plasma ignition, thereby providing a smoother transition to impedance levels at plasma ignition during high temperature and high pressure deposition operations. This smoother transition eliminates arcing between the faceplate 200 and the semiconductor substrate during plasma ignition, which helps protect the faceplate 200 and prevents defects on the semiconductor substrate. Additionally, the elimination of arcing enables high temperature and high pressure deposition operations to be performed, which may prevent film shrinkage and provide a stronger film on the semiconductor substrate.

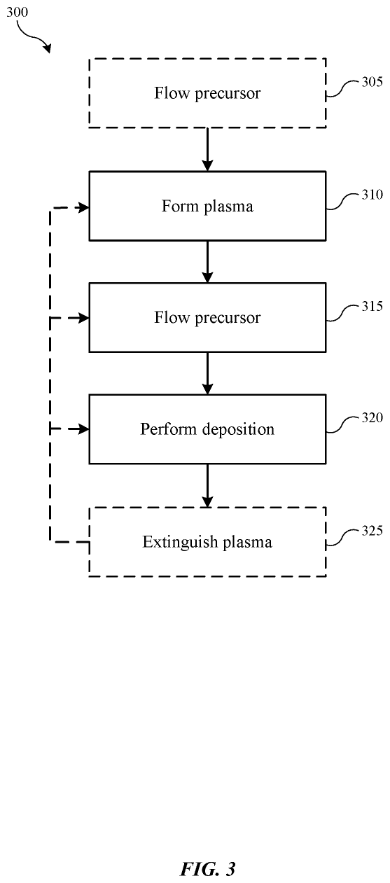

FIG. 3 shows exemplary operations in a method 300 of deposition according to some embodiments of the present technology. The method may be performed in one or more chambers, including any of the chambers previously described, and which may include any previously noted components, or utilize any methodology previously discussed subsequent processing. Method 300 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. For example, and as described previously, operations may be performed prior to delivering a substrate into a processing chamber, such as processing chamber 100 described above, in which method 300 may be performed.

Method 300 may include flowing an oxygen-containing precursor into a processing region of a semiconductor processing chamber at optional operation 305. Although any number of oxygen-containing precursors may be used in embodiments of the present technology, in some embodiments the oxygen-containing precursor may be diatomic oxygen. The methods may include forming a plasma of an oxygen-containing precursor within a processing region of a semiconductor processing chamber at operation 310. The processing region may house a substrate, such as on a substrate support, and on which the deposition process may be performed. Any number of oxygen-containing precursors may be utilized including diatomic oxygen, ozone, nitrogen-containing precursors that incorporate oxygen, water, alcohol, or other materials. During the plasma formation initially, the processing region may be maintained substantially or completely free of a silicon-containing precursor, such as tetraethyl orthosilicate (“TEOS”) or any other silicon-containing precursor. Any number of inert or carrier gases may be delivered with the oxygen, including, for example, helium, argon, nitrogen, or other materials.

Subsequent a first period of time, and while the plasma of the oxygen-containing precursor is maintained, a silicon-containing precursor may be flowed into the processing region of the semiconductor processing chamber at a target flow rate at operation 315. The precursor may be flowed into the chamber via a gas distributor having a faceplate similar to faceplate 200 described above. For example, the faceplate may define a plurality of apertures through a thickness of the faceplate. The apertures may be sized, numbered, and tightly spaced together so as to increase the amount of area of the faceplate that is formed by the apertures. For example, an area of the portion of the faceplate that is exposed to the interior of the chamber may be formed of at least or about 10% apertures and the faceplate may have an impedance of greater than or about 5.75 deciohms. The increased impedance of the faceplate provides a smoother transition between impedance levels during high temperature and high pressure deposition operations, which eliminates arcing between the faceplate and the semiconductor substrate during plasma ignition, thereby protecting the faceplate and preventing defects on the semiconductor substrate. In some embodiments, the silicon-containing precursor may include TEOS, which may be characterized by a lower sticking coefficient than other silicon-containing precursors, such as silane.

A number of deposition operations may then be performed at operation 320, which may include proceeding with deposition at the target flow rate to produce a desired film thickness. The deposition operations may be performed at temperatures of about or at least 425° C., about or at least 450° C., about or at least 475° C., about or at least 500° C., about or at least 525° C., about or at least 550° C., about or at least 575° C., or more. The deposition operations may be performed at pressures of about or at least 7.5 torr, about or at least 7.75 torr, about or at least 8.0 torr, about or at least 8.25 torr, about or at least 8.5 torr, about or at least 8.75 torr, about or at least 9.0 torr, or more. By performing the deposition at higher temperatures and pressures, the methods reduce film shrinkage and result in a greater film strength on the semiconductor substrate. Additionally, by performing processes according to method 300, during subsequent etching operations, such as during a wet or dry etch, undercut etching at the film interface with an underlying structure may be minimized or prevented. While many conventional processes may have a higher likelihood of arcing at these processing conditions, the present technology may perform the processes with no arcing by utilizing a higher impedance faceplate.

Additionally, in some embodiments the methods may also include extinguishing the plasma at optional operation 325. In some embodiments, the oxygen-containing precursor, such as oxygen, may be flowed continuously throughout this process, which may maintain pressure characteristics within the processing chamber, and may also operate as a purge of deposition byproducts. Consequently, the surface of the first deposited material may be cleaned by the flowing oxygen precursor. The process may then repeat to form another section. For example, the plasma may be reformed from the oxygen-containing precursor, and the silicon-containing precursor may be reflowed into the processing region. The operations may be similar to as previously performed to produce a second section of deposited material, where the flow rate of the silicon-containing precursor may be ramped over a period of time, which may be the same or different than in the first section of material deposited. Consequently, a film characterized by increased density may be formed through these repeated operations, which may be repeated any number of times. By utilizing diatomic oxygen as the oxidizing precursor, an increased deposition rate may be provided, which may produce films characterized by improved shrinkage characteristics over conventional techniques, utilizing chambers that will limit or prevent arcing during the semiconductor processing.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A deposition method comprising:
forming a plasma of an oxygen-containing precursor within a processing region of a semiconductor processing chamber, wherein the processing region houses a semiconductor substrate on a substrate support;
while maintaining the plasma of the oxygen-containing precursor, flowing a silicon-containing precursor through a faceplate into the processing region of the semiconductor processing chamber, wherein the faceplate has an impedance of at least about 5.75 deciohm; and
depositing a silicon-containing material on the semiconductor substrate.

2. The deposition method of claim 1, wherein:
the silicon-containing precursor comprises tetraethyl orthosilicate.

3. The deposition method of claim 1, wherein:
the depositing is performed at a temperature of greater than or about 450° C.

4. The deposition method of claim 1, wherein:
the depositing is performed at a pressure of greater than or about 8 torr.

5. The deposition method of claim 1, wherein:
at least about 10% of an area of the faceplate that is exposed to an interior of the chamber is formed by a plurality of apertures defined by the faceplate.

6. The deposition method of claim 1, wherein:
the faceplate comprises at least or about 75 rows of apertures.

7. The deposition method of claim 1, wherein:
the faceplate defines greater than or about 25,000 apertures.

8. The deposition method of claim 1, wherein:
the faceplate defines a plurality of apertures arranged in a uniform manner about a surface of the faceplate.

9. The deposition method of claim 8, wherein:
centers of adjacent ones of the plurality of apertures are spaced apart by less than or about 80 mils.

10. A deposition method comprising:
flowing an oxygen-containing precursor into a processing region of a semiconductor processing chamber, wherein the processing region houses a semiconductor substrate on a substrate support;
forming a plasma of an oxygen-containing precursor within a processing region of a semiconductor processing chamber;
flowing a silicon-containing precursor through a faceplate into the processing region of the semiconductor processing chamber, wherein:
the faceplate defines a plurality of apertures through a thickness of the faceplate; and
at least about 10% of an area of the faceplate that is exposed to an interior of the chamber is formed by the plurality of apertures; and
depositing a silicon-containing material on the semiconductor substrate.

11. The deposition method of claim 10, wherein:
a distance between outermost apertures of the plurality of apertures that are proximate opposing sides of the faceplate is about or at least 13 inches.

12. The deposition method of claim 10, wherein:
each of the plurality of apertures comprises an aperture profile having a first generally cylindrical section extending through the first surface of the faceplate and a second generally cylindrical section extending through the second surface of the faceplate.

13. The deposition method of claim 12, wherein:
a diameter of the first generally cylindrical section is more than or about 1.3× greater than a diameter of the second generally cylindrical section.

14. The deposition method of claim 12, wherein:
the first generally cylindrical section extends at least or about halfway through a thickness of the faceplate.

15. The deposition method of claim 10, wherein:
the depositing is performed at a temperature of greater than or about 450° C. and a pressure of at least about 8 torr.

16. A semiconductor processing chamber, comprising:
a chamber body;
a substrate support disposed within the chamber body; and
a gas distributor comprising a faceplate, wherein:
the faceplate is characterized by a first surface and a second surface opposite the first surface, the second surface facing the substrate support;
the second surface of the faceplate and the substrate support at least partially define a processing region within the semiconductor processing chamber;
the faceplate defines a plurality of apertures through the faceplate;
the faceplate has an impedance of at least about 5.75 deciohm; and
at least about 10% of an area of the faceplate that is exposed to an interior of the chamber is formed by the plurality of apertures.

17. The semiconductor processing chamber of claim 16, wherein:
each of the plurality of apertures comprises a generally cylindrical aperture profile.

18. The semiconductor processing chamber of claim 17, wherein:
the aperture profile of each of the plurality of apertures comprises an additional cylindrical section that extends through the first surface of the faceplate; and
the additional cylindrical section has a greater diameter than the generally cylindrical aperture profile.

19. The semiconductor processing chamber of claim 18, wherein:
a diameter of the generally cylindrical aperture profile is less than or about 35 mils; and
a diameter of the additional cylindrical section is less than or about 50 mils.

20. The semiconductor processing chamber of claim 16, wherein:
the plurality of apertures comprises at least or about 25,000 apertures.
